(19) United States
(12) Patent Application Publication
(10) Pub. No.: US 2004/0163697 A1
(43) Pub. Date: Aug. 26, 2004

(54) Triple hybrid solar concentrated type system for the simultaneous production of electrical, thermal and cooling energy

(76) Inventor: Alexandros Papadopoulos, Dionyssos (GR)

Correspondence Address: Himanshu S Amin, Amin & Turocy, 24th Floor, 1900 East 9th Street, Cleveland, OH, 44114, US

(21) Appl. No.: 10/474,570

(22) PCT Filed: Apr. 8, 2002
(86) PCT No.: PCT/GB02/00024

(30) Foreign Application Priority Data
Apr. 12, 2001 (GR) 20010100192

(51) Int. Cl. H01L 25/00

(52) U.S. Cl. 136/246

(57) ABSTRACT

A concentrating type Hybrid Photovoltaic (P/V) Systems for the simultaneous production of electrical, thermal and cooling energy by using total reflection (or conventional) mirrors (301a), which are produced by impression of glass. With the use of concentrating type PV Cells (302a), on which the concentrated solar energy is focused, electrical energy is produced, with simultaneous production of hot water from the cooling of the PV Cells or also overheated oil by partial focusing of solar radiation upon the PV Cells and the rest of the radiation in a special heating oil focal cavity (900a). Also, with the use of special Adsorption Heat Pumps, which convert the thermal power of the produced low temperature hot water into cooling power, it is possible the direct utilization of the produced hot water in the summer for air conditioning and in the winter directly for space heating.

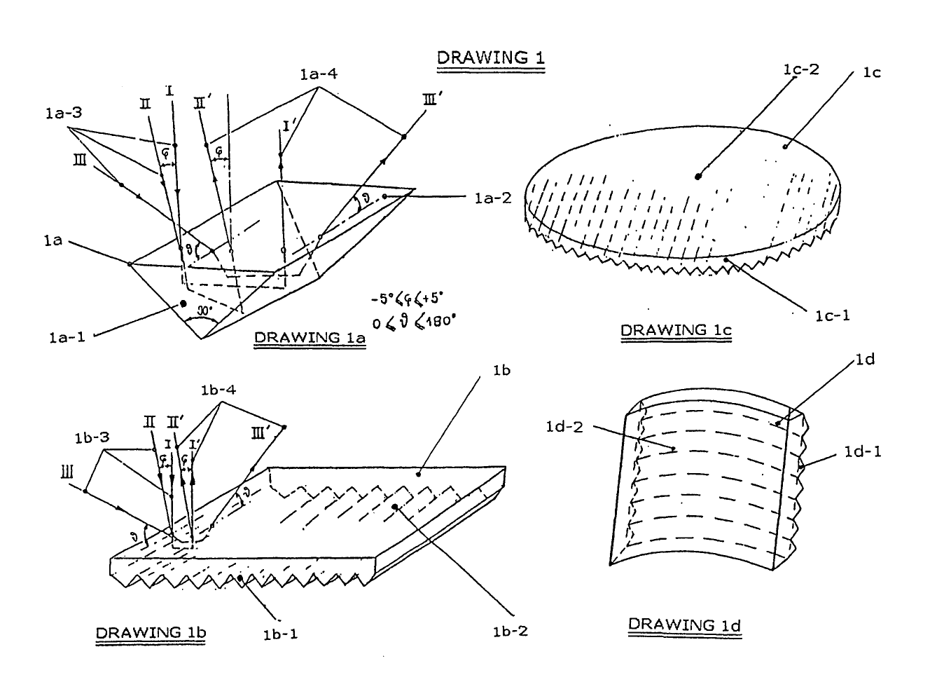

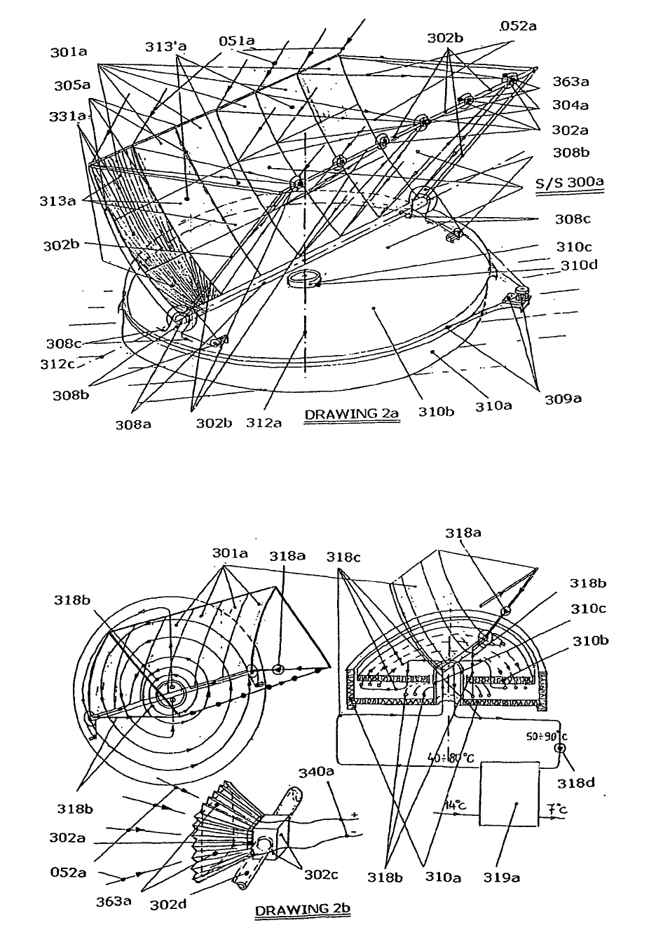

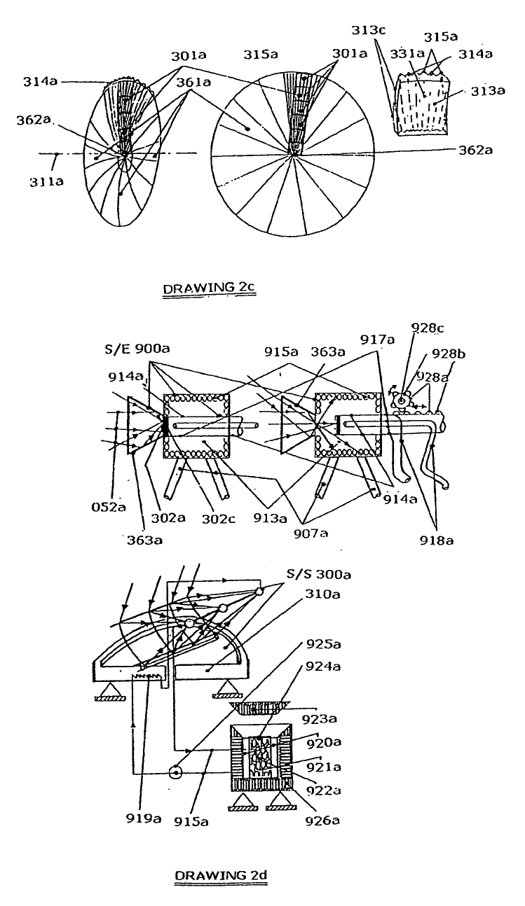

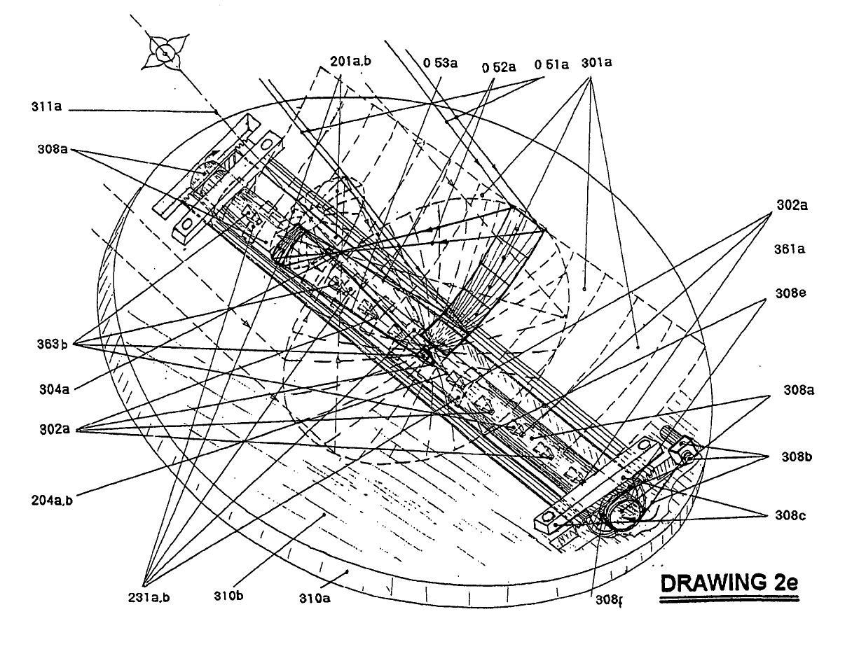

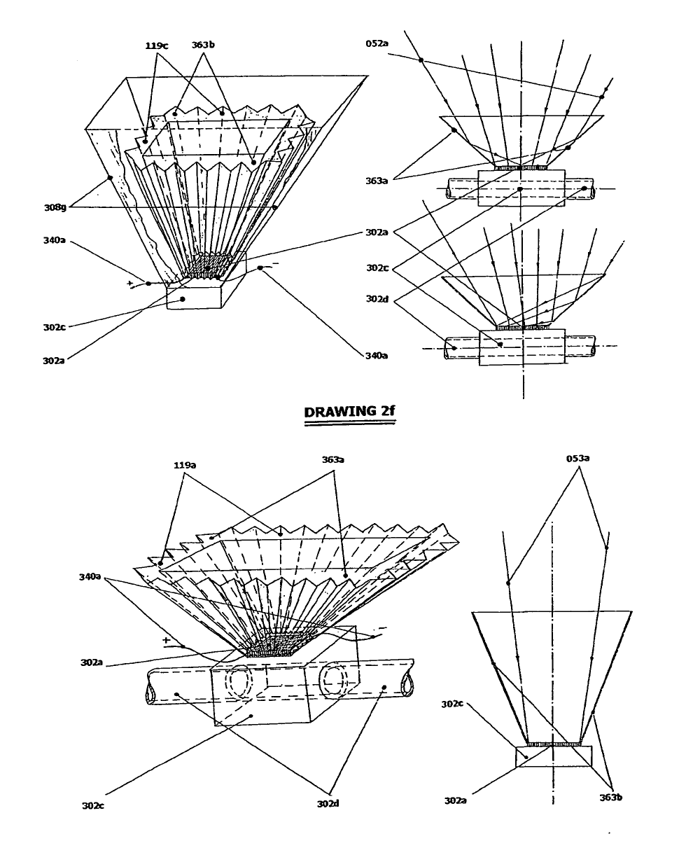

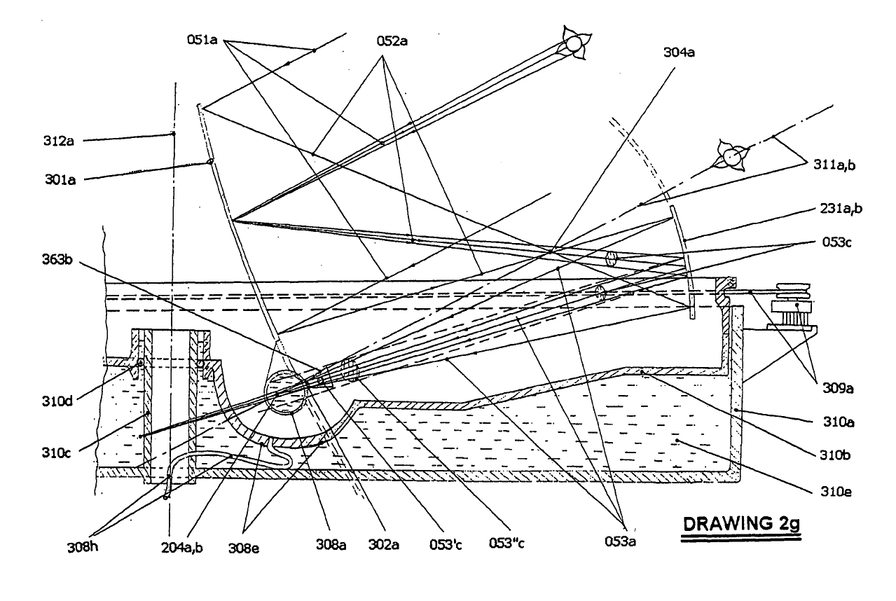

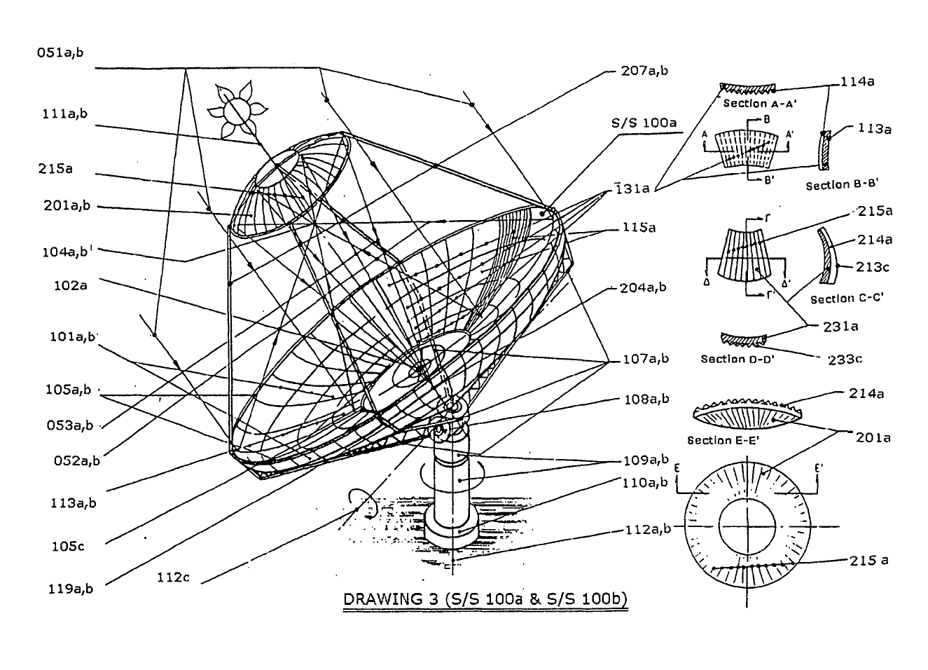

### A. GENERAL—FIELD REVIEW

The present invention refers to concentrating type photovoltaic (PV) systems, which produce electric energy by using concentrating type PV cells, upon which focuses the concentrated solar energy with simultaneous production of hot water from the cooling of the PV cells or also overheated oil with focusing of a part of the solar radiation on the P/V cells and the rest part of the radiation on a specially formatted focal cavity for the heating of oil. Also, with the use of special air-conditioning systems, which convert the thermal energy of the hot water (of relatively low temperature) into cooling energy, the direct utilization of the produced hot water for space air conditioning during summertime is possible.

The concentrating type solar systems are widely known in various types and combinations for concentrating type Photovoltaic (PV) or for Solar Thermal Systems or for other systems with concentration ratios from 2 up to about 1000 suns. Nevertheless, they are not used in big extent for the production of electrical or thermal energy from the Sun, because of the big specific cost of the produced energy (per KWH or per Kcal produced) compared to the similar production of energy from conventional fuels.

The main reason which increases the cost of concentrating type solar systems (and makes these systems economically not feasible) is the fact that they are constituted by big reflective surfaces, which are rotated in order to track and focus the Sun, thus presenting a big interception surface to the wind. Therefore, in order to survive from the maximum expected wind speed during their lifetime, an especially careful design and an exceptionally heavy construction must be foreseen, which increases the cost in prohibitive heights.

The use also of conventional silver coated mirrors, which deteriorate after several years of exposure to the severe outside conditions, was limiting the system life thus making its exploitation not economical.

The use also of concentration ratios above 1000 suns required high precision parabolic mirrors and was limited by the size of the solar idol, thus making high concentration ratios not feasible. Furthermore, the concentrating type PV cells present problems of deterioration of their efficiency due to the uneven distribution of the incident concentrated solar radiation on their surface.

Also the use of hot water (with temperatures of 50-70° C.) from the cooling of the PV cells for the production of cold water for air conditioning with adsorption systems, was not economically feasible and it has not been applied so far.

### B. GENERAL DESCRIPTION OF THE ADVANTAGES OF THE PRESENT INVENTION

In the present invention innovative and economically acceptable solutions to the previous problems are given and the devolvement of innovative Solar Systems (S/S) and innovative Structural Elements (S/E), which allow overcoming the obstacles and permitting the economic production of electrical, thermal and cooling energy from the Sun, is presented. The most important of them (and not only them) are the following:

a) The innovative Solar Reflectors of Total (or Simple Conventional) Reflection with a low profile or profile with low resistance to the Wind (S/E 301, 313, 101, 201 etc)

b) The innovative Total Reflection Mirrors (TRM) (S/E 131, 331, 231,1b, 1c, 1d etc). The TRM are made by common water clear glass by impressing, with low cost, they reflect almost 100% of the incident solar radiation and guarantee a practically unlimited life.

c) The innovative secondary paraboloidal TRM (or conventional mirrors), which permit a drastic reduction of the solar idol size thus permitting very high concentration ratios.

d) The innovative PV Systems for the exploitation of more than 80% of the solar energy incident on the PV Cells by the production of electricity, hot water from the cooling of the PV cells and chilled water from the hot water during summer for air conditioning, using silica gel adsorption heat pumps.

e) The innovative focal systems for the production of hot water from the cooling of the PV cells or of a slightly overheated one in order to increase the production of cooling energy by using overheated oil (Focus S/E 900).

f) The combination of concentrating type PV with adsorption type heat-pump units, which produce cooling energy by using for example silica gel. These units utilize low temperature hot water in order to produce cold water for air conditioning or cooling in refrigerators or refrigerators rooms etc.

The wide use of the Hybrid Solar Systems of the present invention will make feasible the production of such Triple Hybrid Solar Systems with low cost, high reliability and duration of life beyond 20 years, which will be able to produce simultaneously for example for residences (or buildings) electrical energy, hot water, cold water for air conditioning or refrigerating rooms, heat for cooking, space heating etc. thus making possible the exploitation of almost the total (more than 80%) of the solar energy incident on the P/V cells (contrary to the current applications of PV, which utilize only the 10-25% of the incident solar energy that is only for the production of electricity). The multiple exploitation of the incident solar energy in such high percentages increases the feasibility of the hybrid Solar Systems of the present invention and makes the production of energy from them competitive to the conventional sources of energy

### C. DESCRIPTION OF THE DRAWINGS OF THE INVENTION

The Drawing 1a presents the process of Total Reflection while the Drawing 1b, 1c and 1d show the typical forms of Total Reflection Mirrors (TRM).

The Drawing 2a presents the Hybrid Solar System in axonometric view.

The Drawing 2b presents the Hybrid Solar System in ground view and in section.

The Drawing 2c presents a detail showing the construction of the TRM 301a of the Hybrid Solar System S/S 300a as an extract of the Complete Parabolic Mirror 361a.

The Drawing 2d presents the Focus S/E 900a of the Hybrid Solar System S/S 300a

The Drawing 2e presents details for the construction of the S/S 300b with secondary paraboloidal TRM (or conventional ones) and PV cells placed at the final focus and cooled directly by the storage water.

The Drawing 2f presents details for the construction of the Focus Mirrors 363a suitable for the first or for the final focus.

The Drawing 2g presents details of the innovative secondary paraboloidal TRM (or conventional mirrors), which permit a drastic reduction of the solar idol size thus permitting very high concentration ratios.

The Drawing 3 presents the S/S 100a,b in axonometric view.

### D. DETAILED DESCRIPTION OF THE STRUCTURAL ELEMENTS AND SOLAR SYSTEMS OF THE PRESENT INVENTION

1. The Total Reflection Mirrors (TRM)

The Drawing 1 shows the known process of Total Reflection (TR) of the Rays 1a-3 (I, I, III entering the Prism 1a) and 1a-4(I′, II′, III′ coming out from the Prism 1a), when they enter in the orthogonal Glass Prism 1a (the Front Surface 1a-2 is flat while the Rear Surface 1a-1 is an orthogonal prism) with the known limitations for the angles of entrance Φ and θ (i.e for coefficient of diffraction of glass η=1.52 the Lateral Angle Φ should be −5°<Φ<5° in order to achieve Total Reflection while for the Along Angle θ it is valid that 0<θ<180°)

The Drawing 1b shows a Total Reflection Tablet TRT or TRM 1b, which is characterized by its small thickness (i.e. 5-10 mm) from transparent material (i.e water clear glass or transparent plastic i.e. Polycarbonate or Plexiglas etc with coefficient of diffraction <<n>> higher than 1.5 approx.) with the Front Surface 1b-2 being flat while the Rear Surface 1b-1 being bas-relief consisting of many parallel orthogonal prisms. It is obvious that the incoming Rays 1b-3 (I, II, III) with the same angles of entrance such as the ones 1a-3 in the Prism 1a (in Drawing 1a), will undergo total reflection with exactly the same way and the same restrictions, for the angles of entrance etc, such as in the case of Prism 1a. Therefore, the Total Reflection Tablet 1b represents a Total Reflection Mirror (TRM), which is characterized by its low cost of production from common water clear glass or from transparent plastic by impressing in existing automatic machines with high production capacity (i.e automatic machines for the production of glasses etc) or by Extruder for the plastic etc, the TRT doesn't need plating with Silver in order to make reflection and it doesn't appear aging etc. Furthermore it is characterized by the fact that the TRM 1b (and all the TRM in general) presents important advantages, due to the Lateral Particularity of Total Reflection {because when i.e. the Ray II enters with a lateral angle Φ to the vertical (with −5°<Φ<5°), it comes out with the same angle Φ and from the same side of the prism which the ray had entered, in the contrary to the conventional mirrors, where the reflected Ray II′ would come out from the opposite side to the vertical to that it had entered} such as, for example a) maintaining the focus for a vibration of the TRM by +/−5° round an axis parallel with the along acme of the prism, b) possibility of drastic reduction at the size of solar Idol by reflectance on a secondary TRM and thereinafter focusing etc.

It is also characterised by the fact that Total Reflection is the only known process of reflection in nature, in which we have practically reflection of the 100% of radiation and in this way if allows by using TRM 1b etc the construction of Concentrating Solar Systems with multiple reflections before the final focus, with losses smaller than the losses from a single reflection in the concentrating systems with conventional mirrors.

In the Drawings 1c and 1d, two different forms of Total Reflection Mirrors are shown, as the TRM 1b above, which are characterised by the fact that the Drawing 1c presents a flat Total Reflection Disk (TRD) 1c (with the Front Surface 1c-2 being flat while the Rear Surface 1c-1 being bas-relief with many parallel orthogonal prisms). The Drawing 1d shows a Total Reflection Tablet (TRT) 1d (with the Front Surface 1d-2 being cylinder-parabolic while the Rear Surface 1d-1 being also cylinder-parabolic bas relief with many parallel orthogonal prisms), while several other types of TRM or TRT as the above, are described in the following and are used for the construction of for example High or Low-Profile Total Reflection Mirrors i.e. with TRM 301a, 131a, 131b, 201a,b, 231a,b, 363a etc in various versions of the S/S 300a, S/S 100a,b etc of the present invention.

2. The Solar System of Multiple Point Focusing SIS 300a

The Solar System S/S 300a which is described here and it is shown in the Drawings 2a, 2b, 2c and 2d is characterized by the fact that it is of the concentrating type, multiple point focusing, with a Reflecting Surface 313a that is constituted by many parallel Total (or simple Conventional) Reflection Mirrors TRM 301a, of low profile, in order not to present high interception surface to the wind and its rotation around the vertical Axis of Symmetry 312a of the System is being effected by the seating of the Reflecting Surface 313′a (=The total of all 313a) upon the Base of Rotation 310b, which either floats and is rotated on the Heat Storage Water 310e (water with anti-freezing) that is contained in a Water Container 310a or alternatively it is rotated supported by the conical Rotation Bearing 310d on the Passing Through Cylinder 310c (or with the combination of both methods) with the help of the Vertical Rotation Mechanism 309a.

Furthermore, it is characterised by the fact that the Solar Rays 051a after falling on the primary parabolic TRM with Top of parabola the point 301a, then create the first reflected Wide Beam of Rays 052a, which focalises in the focus 304a and either they are utilized directly there [focusing on the PV Cells 302a with the help also of the secondary truncated pyramidal (or conical) total (or conventional) reflection Focus Mirror 363a], or alternatively they (the 052a) can create, after reflection on the paraboloidal Secondary Mirror 231a,b (as extract of the relative complete paraboloidal Secondary Mirror 201a,b), the Narrow Beam of Rays 053a,b that reaches the Final Focus 204a,b and focuses on the PV cells 302a through the relative Final Focus Mirror 363b, too.

Each of the TRM 301a constitutes an orthogonal, parallelogram extraction from a Complete Parabolic Mirror (of total or conventional reflection) 361a. Each of the TRM 301a can be one piece or be constituted from 2, 3, 4 or more Tiles of Total Reflection (TTR), which are fixed on a suitable parabolic substrate with dimensions approximately 20×20 cm (each of them), such that the TTR can be produced with low cost by automatic machines of impressing glass. The material of the TRM 301a is constituted for example from transparent glass without iron oxides (water clear glass) or from transparent plastic self supported or fixed on a suitable substrate.

The Front Surface 313a of the TRM 301a has a smooth parabolic form while the Rear Surface 313c is also parabolic bas-relief and is constituted by many parallel orthogonal Prisms 314a, of which the Top Acmes 315a converge and are intercepted on the Top 362a of the complete Parabolic Mirror (PM) 361a. We have also the Symmetry Axis 311a (which aims the Sun) and the Rotation Axes 312a and 312c (Vertical and Horizontal respectively).

The TRM 301a is supported on the metallic Supporting Rack 305a, which in its turn is supported on the Horizontal Rotation Axis 308a, which carries at its both ends the Pulleys and the Mechanism of Horizontal Rotation 308b and with the help of the two Bearings 308c it is supported on the Base of Rotation 310b.

The Storage Pot 310a is constituted by an insulated pot of water which is full with Water and Anti-freezing 310e and bears the Rotation Base of 310b which is rotated around the Passing Trough Cylinder 310c using the Vertical Rotation Mechanism 309a.

The PV Cells 302a are supported on the metallic Supporting Rack 302b which is supported on the Horizontal Rotation Axis 308a. The PV Cells are placed in the focus of each TRM 301a and they bear on their front side, the Focus Mirror of total (or conventional) reflection 363a and on their rear side, a copper Cooling Plate 302c, that bears welded on it the Cooling Pipe 302d and it is cooled by the Cooling Fluid 302e (i.e. water plus anti-freezing), which flows through the 302c.

The Cooling Fluid 302e circulates with the help of the Circulating Pump 318a, in the closed circuit that is created by the Spiral Heat Exchanger 318b that is installed in the bottom of the Storage Pot 310a. Thus the heat which is carried away from the PV Cells 302a through the Cooling Fluid 302e and the Spiral Heat Exchanger 318b is transported into the Heat Storage Water 310e of the Storage Pot 310a. From there the heat is received by a Second Spiral Heat Exchanger 318c and through the Circulating Pump 318d goes either to the consumption as domestic hot water or in the Adsorption Pump 319a in order to deliver the thermal energy that is required for the production of cold water 5/12° C. or 7/14° C. for air conditioning, supported eventually by auxiliary hot water production boilers fired by conventional fuels, in order to cover periods of low solar radiation or non availability of the solar driven units.

The direct current which is produced by the PV Cells 302a is carried away by the Cables 340a and it is led either directly in batteries or in inverters of direct/alternating current for use by users of alternating current.

3. The Solar System of Multiple Point Focusing S/S 300b

The Solar System S/S 300b, which is described here and it is shown in the Drawings 2e, 2f and 2g is characterized by the fact that it is of the same construction as the S/S 300a described in Paragraph 2 above but it is characterized by the fact that the first reflected Wide Beam of Rays 052a, which focalises in the first Focus 304a can create, after reflection on the paraboloidal Secondary (of total or conventional reflection) Mirror 231a,b (as extract of the relative complete paraboloidal Secondary Mirror 201a,b), the Narrow Beam of Rays 053a,b that reaches the Final Focus 204a,b and is characterized by the possibility of drastic reduction of the size of the Solar Idol 053c (of the Solar Image when reflected, as shown also in the Drawing 2g), thus permitting concentration ratios in the order of 1000-2000 suns or even more and focuses on the PV Cells 302a lying at or behind the Final Focus 204a,b through the Final Focus Mirror 363b.

By that also in this position the Cooling Plates 302b of the PV Cells 302a can also be brought in direct contact with the Storage Water 310e, which means that in this case the Cooling Pipes 302d, the Circulating Pump 318a and the Spiral Heat Exchanger 318b are not needed any more and are deleted.

By that the Focus Mirror 363a (as shown in the Drawing 2f), as a TRM, is constructed either by four Total Reflection Tiles forming a truncated pyramid around the PV Cells 302a with the acmes of their orthogonal prisms converging towards the top of the pyramid formed by them (or even from conventional mirrors air- or water-cooled) with a suitable opening angle towards the primary TRM 301a permitting it to compensate small aiming misalignments of the sun-tracking system or imperfections of the TRM 301a. The Focus Mirror 363a can also be found at the Final Focus 204a,b (or at each Final Focus 204a,b of the successive TRM 301a combined each with its relative Secondary Mirror 231a,b as extract of the relative complete paraboloidal Secondary Mirror 201a,b), when a paraboloidal Secondary Mirror 231a,b is used to reflect back the Wide Beam 052a and form the Narrow Beam 053a,b towards the Final Focus 204a,b (named then Final Focus Mirror 363b).

By that also the Horizontal Rotation Axis 308a in the case that the PV Cells 302a are positioned at the Final Focus 204a,b can either carry fixed on it the Cooling Plates 302c [in such a case the Axis 308a will be hollow and being cooled by the Cooling Fluid 302e, which flows through it either circulated by the Circulating Pump 318d or directly by gravity when both ends of the Axis 308a are submerged in the Storage Water 310e (while the fixed on it Solar Cells 302a are protected from the water by the specially formulated watertight submerged Basin 308e around the submerged Axis 308a, which is drained from parasitic water by the Drainage Pipe 308h going out through the central Passing Through Cylinder 310c), while both ends of the 308a go through the end walls of the Basin 308e, into the Storage Water 310e, by the flexible Connections 308f permitting watertight rotation of the 308a by +/−90° in order to truck the Sun] or can incorporate suitable openings containing the Final Focus Mirrors 363b with attached at their ends the PV Cells 302a, which in this case will be, through their Cooling Plates 302c, in direct contact with the Storage Water 310e and thus being directly cooled by it (the Solar Cells 302a being protected from the water by their watertight Basins 308g around each of the Final Focus Mirrors 363b).

In this later case as well as in the case of the submerged Axis 308a above, with fixed on it the PV Cells 302a, the Cooling Pipes 302d, the Circulating Pump 318a and the Spiral Heat Exchanger 318b, are not needed any more and they are consequently deleted.

By that also in the position of the submerged Horizontal Rotation Axis 308a the Bearings 308c are fixed on the specially arranged 310b with their head downwards coupled respectively with the relative Mechanism of Horizontal Rotation 308b.

It is further characterized by the special arrangement and positioning of the primary TRM 301a and the Secondary Mirror 231a,b as extracts of the complete Mirrors 361a and 201a,b, as shown with dotted lines in the Drawing 2e.

4. The Focus Structural Element (S/E) 900a of the S/S 300a

The Focus Structural Element (S/E) 900a, which is described here and it is shown in the Drawing 2d, is characterized by the fact that it is designed for the simultaneous production of electricity, hot water (from the cooling of the PV Cells) and overheated oil (for cooking as well as for overheating of the domestic hot water as well as for the regulation of the ratio in the production of electrical and thermal energy of the S/S 300a or of whatsoever other relevant concentration PV System).

It is also characterized by the fact that the Sun's Rays 051a after their falling on the relative Primary Parabolic Mirror i.e 301a with its Top at the point 362a, they create the reflected wide Beam of Rays 052a which first focalizes on the Focus 304a and afterwards falls on the PV Cells 302a. The PV Cells can be found either at the Opening 912a of the Cavity 913a (which can i.e coincide with the Focus 304a), whereupon all the concentrated solar radiation (Wide Beam 052a) falls through the 363a on the PV Cells 302a and is absorbed by them. The PV Cells can also be found in whatsoever depth in the Cavity 913a (moving backwards, in the Cavity 913a, the Cylinder of Support/Cooling 914a of the PV Cells 302a) whereupon only a part of the Wide Beam 052a falls and is absorbed on the PV Cells 302a, while the rest falls on the Oil Pipes 915a, that cover the interior of the Cavity 913a, and is absorbed there by the special Overheating Oil 916a (which can reach temperatures up to 300°-400° C.).

The percentage of the concentrated solar radiation of the Wide Beam 052a, which is absorbed by the PV Cells 302a and by the Overheating Oil 916a, is dependant on the position of withdrawal (or positioning) of the PV Cells 302a in the Cavity 913a and it is possible to be decreased to very small percentages for the extreme position of the PV cells (i.e. 5%), resulting to a relative increase of the absorbed percentage by the Overheated Oil 916a which absorbs then the 95%.

It is also characterized by the Cylinder of Support/Cooling 914a of the PV Cells 302a which supports the PV Cells 302a while simultaneously, through the concentric Cooling Pipes 917a, transports and abducts the Cooling Fluid 302e of the PV Cells 302a. The Cooling Pipes 917a are linked, through the Flexible Pipes 918a, with the Pipes 302d of transportation to and from of the Cooling Fluid 302e. The Cooling Fluid 302e is conducted by them to the Spiral type Heat Exchanger 318b in the hot water Container 310a. It is also characterized by the fact that the movement in and out of the cavity 913a, of the Cylinder of Support/Cooling 914a is effected by the Mechanism 928a, which is constituted by the Moving Screw 928c that is connected with the Displacement Screw 928b which is fixed on the Supporting Cylinder 914a, from the Movement Screw 928c, which is coupled with the Displacement Screw 928b, from the Coupling Axle 928d which connects the Movement Screws 928c of the successive S/E 900a (one for each TRM 301a) and from the Motor 928e which is connected with the Axis of Coupling 928d, eventually through a reduction gear, and via the elements 928c and 928b transmits the movement forwards-backwards to the Cylinder 914a. Also by the fact that the Oil Tubes 915a, which cover the interior of the Cavity 913a are conducted to the Exchanger 919a inside the hot water Container 310a and increase the temperature of the Storage Water 310e which originates from the cooling of the PV cells 302a, to the desired temperature.

Also by the fact that before the Pipe of Overheated Oil 915d reaches the Exchanger 919a it can pass first trough the Exterior Mantle 920a of the high temperature Storage Container 921a, where thermal energy is stored in high temperature in the Eutectic Salt 922a, which is contained in the Storage Container 921a and subsequently is led in the Exchanger 919a. Also by the fact that the Storage Container 921a bears a strong Insulation 926a with a removable Insulated Tap 923a of the upper Heating Plate 924a of the Container 921a, so that when the Insulated Tap 923a is removed the Heating Plate 924a can be used as a Cooking Herd in hours outside the peak of solar energy. Also by that the Overheated Oil 916c circulates in the Oil Pipes 915a via the Circulator 925a and the Cooling Fluid 302e circulates in the Pipes 302d via the Circulator 318a. Also by that the Focus S/E 900a is supported on the correspondent Frame of Support 302b of the correspondent S/S i.e 300a (or whatsoever else concentrating PV System) via the 4 Supports 907a which can simultaneously play in pairs the role of the Water Pipes 302d and of the Oil Pipes 915a.

5. The Solar System of Single Point Focus S/S 100a,b with Total (or Conventional) Reflection Mirrors for Very High Concentration Ratios

The S/S 100a,b, where with (a) is designated the S/S 100 when employing Total Reflection Mirrors and with (b) when employing Conventional Mirrors), that is described here and is shown in the Drawing 3 is characterized by that it includes a complete primary Parabolic of Total (or simple Conventional) Reflection Mirror PTRM 101a,b with its Top at the point 102a,b (which is further characterized by its Total Reflection Tiles (TRT) 131a, with their Front Surface 113a and their back Orthogonal Prisms 114a) and where the Solar Rays 051a after falling on the primary PTRM 101a,b create the first reflected Wide Beam of Rays 052a,b, which focus on the First Focus 104a,b and either they are exploited directly there by focusing on the PV Cells 302a,b with the help also of the Focal Mirror 119a,b (which is identical to the Focal Mirror 363a of Paragraph 1 above) or alternatively after reflection on the Secondary Mirror 201a,b (that is supported via the Arms 207a,b on the Ring 105a,b), they create the Narrow Beam of Rays 053a,b, which reaches the Final Focus 204a,b and focuses on the PV Cells 302a,b also by the help of the Final Focus Mirror 119c, (being identical to the Final Focus Mirror 3263b), which is supported on the Ring 105c.

By that also the combination of the above Mirrors 101a,b and 201a,b (or whatsoever extracts of them correspondent to each other) is characterized by the possibility of drastic reduction of the size of the Solar Idol 053c (of the Solar Image when reflected), by reflectance of the Solar Rays 051a first on the PTRM 101a, forming the Wide Beam 052a and then by a second reflectance of the Wide Beam 052a on the concave paraboloidal Secondary Mirror 201a,b located behind the relative Focal Point 104a, thus forming the Narrow Beam 053a, which when focusing, under certain relations of sizing between the Mirrors 101a,b and 201a,b, can drastically reduce the size of the Solar Idol 053c (for example for a ratio of the diameter of the 101a,b to the one of the 201a,b equal to 4, the size of the Solar Idol 053′c at the Final Focus 204a,b can be reduced under the 20% of the size, which the Solar Idol 053′c would have without suppression by the combination of the 101a,b and 201a,b as above) and so the concentration ratio of the relative S/S 100a,b can be increased to figures over 2000 Suns.

By that also the PTR Mirror 101a,b is supported on the metal Support Rings 105a,b (Exterior) and 105c (Interior) which on their turn are supported by the metal Support Arms 107a,b which are supported on the Head of Horizontal Rotation 108a,b. The Head 108a,b is supported on the Column of Vertical Rotation 109a,b which is based on the Base 110a,b, which can be either a fixed ground or a Floating and Rotating Base 110a,b rotating to track the Sun, like the Base of Rotation 310b in Paragraph 1 above (in this case the Column of Vertical Rotation 109a,b will not be needed and will be deleted). By that also the Floating and Rotating Base 110a,b can carry on it one or more S/S 100a,b either with a complete primary Parabolic Total Reflection Mirror (PTRM) 101a,b or with a sector only of the PTRM 101a,b or whatsoever extract of the PTRM 101a,b and relative sectors or extracts of the secondary Paraboloidal Mirror 201a,b.

By that the Parabolic Total Reflection Mirror 101a is constituted for example from transparent water clear glass without iron oxides (in a single piece for small surfaces or constituted from Total Reflection Tiles (TRT) 131a that constitute parts of the Parabolic Surface 113′a for bigger surfaces supported on a suitable parabolic substrate) or from transparent plastic self-supported or supported on a suitable substrate. The Front Surface 113a of the 113′a has a smooth parabolic form, while the Rear Surface 113c is parabolic bas-relief and parallel with the 113a and is constituted from Orthogonal Prisms 114a, whose Top Acmes 115a converge and are intercepted at the Top 102a of the PTR Mirror 101a. By that the S/S 100a,b includes also the Axis of Symmetry 111a,b (which aims the Sun) and the Axes of Rotation 112a,b and 112c (Vertical and Horizontal respectively).

It is also characterized by the fact that the S/S 100a,b can include at its First Focus 104a,b, instead of the Focus Mirror 119a,b with the PV cells 302a,b, the paraboloidal Secondary Mirror 201a,b, (which is further characterized by its TRT 231a,b with their Front Surface 213a,b, their back Orthogonal Prisms 214a,b, their Acmes 215a,b converging to its Top 202a,b and their Back Surface 213c), is used to reflect back the Wide Beam 052a,b and form the Narrow Beam 053a,b towards the Final Focus 204a,b, where now the Focal Mirror 119a,b with the PV cells 302a,b will be located, (named then Final Focus Mirror 119a,b).

By that also alternatively the S/S 100a,b can include at its First Focus 104a,b or at its Final Focus 204a,b the Focus Structural Element S/E 900a like the S/S 300a in Paragraph 1 above.

1. A Solar System S/S 300a which is characterized by the fact that it is of the concentrating type, multiple point focusing, with a Reflecting Surface (RF) 313′a that is constituted by many parallel Total (or simple Conventional) Reflection Mirrors TRM 301a of low profile in order not to present high interception surface to the wind.
It is also characterised by the fact that its rotation around the vertical Axis of Symmetry 312a of the System is being effected by the seating of the Reflecting Surface 313′a (=The total of all 313a) upon the Base of Rotation 310b, which either floats and is rotated on the Heat Storage Water 310e (water with anti-freezing) that is contained in a Water Container 310a or alternatively it is rotated supported by the conical Rotation Bearing 310d on the Passing Through Cylinder 310c (or with the combination of both methods) with the help of the Vertical Rotation Mechanism 309a.
It is also characterised by the fact that the Solar Rays 051a after falling on the primary parabolic TRM with Top of parabola the point 301a, they create the first reflected Wide Beam of Rays 052a, which focalises in the focus 304a and either they are utilized directly there [focusing on the PV Cells 302a with the help also of the secondary truncated pyramidal (or conical) total (or conventional) reflection Focus Mirror 363a], or alternatively they (the 052a) can create, after reflection on the paraboloidal Secondary Mirror 231a,b (as extract of the relative complete paraboloidal Secondary Mirror 201a,b), the Narrow Beam of Rays 053a,b that reaches the Final Focus 204a,b and focuses on the PV cells 302a through the relative Final Focus Mirror 363b, too.
Also, by that each of the TRM 301a constitutes an orthogonal, parallelogram extraction from a complete parabolic Total Reflection Mirror 361a and each of the TRM 301a can be one piece or be constituted from 2, 3, 4 or more Tiles of Total Reflection (TTR), which are fixed on a suitable parabolic substrate with dimensions approximately 20×20 cm (each of them), such that the TTR can be produced with low cost by automatic machines of impressing glass [the material of the TRM 301a being constituted for example from transparent glass without iron oxides (water clear glass) or from transparent plastic self supported or fixed on a suitable substrate].
Also, by that the Front Surface 313a of the TRM 301a has a smooth parabolic form while the Rear Surface 313c is also parabolic bas-relief and is constituted by many parallel orthogonal Prisms 314a, of which the Top Acmes 315a converge and are intercepted on the Top 362a of the complete Parabolic Mirror (PM) 361a. By the existence also of the Symmetry Axis 311a (which aims the Sun) and the Rotation Axes 312a and 312c (Vertical and Horizontal respectively).
Also, by that the TRM 301a is supported on the metallic Supporting Rack 305a, which in its turn is supported on the Horizontal Rotation Axis 308a, which carries at its both ends the Pulleys and the Mechanism of Horizontal Rotation 308b and with the help of the two Bearings 308c it is supported on the Base of Rotation 310b.
Also, by that the Storage Pot 310a is constituted by an insulated pot of water which is full with Water and Anti-freezing 310e and bears the Rotation Base of 310b which is rotated around the Passing Trough Cylinder 310c using the Vertical Rotation Mechanism 309a.
Also, by that the PV Cells 302a are supported on the metallic Supporting Rack 302b (which is supported on the Horizontal Rotation Axis 308a) and they are placed in the focus of each TRM 301a and they bear on their front side, the Focus Mirror of total (or conventional) reflection 363a and on their rear side, a copper Cooling Plate 302c, that bears welded on it the Cooling Pipe 302d and it is cooled by the Cooling Fluid 302e (i.e. water plus anti-freezing), which flows through the 302c.
Also, by that the Cooling Fluid 302e circulates with the help of the Circulating Pump 318a, in the closed circuit that is created by the Spiral Heat Exchanger 318b that is installed in the bottom of the Storage Pot 310a and thus the heat which is carried away from the PV Cells 302a through the Cooling Fluid 302e and the Spiral Heat Exchanger 318b is transported into the Heat Storage Water 310e of the Storage Pot 310a and from there the heat is received by a Second Spiral Heat Exchanger 318c and through the Circulating Pump 318d goes either to the consumption as domestic hot water or in the Adsorption Pump 319a in order to deliver the thermal energy that is required for the production of cold water 5/12° C. or 7/14° C. for air conditioning.
Also, by that the direct current which is produced by the PV Cells 302a is carried away by the Cables 340a and it is led either directly in batteries or in inverters of direct/alternating current for use by users of alternating current.

2. A Solar System S/S 300b, which is of the same construction as the S/S 300a described in claim 1 above but it is characterized by that the first reflected Wide Beam of Rays 052a, which focalizes in the first Focus 304a can create, after reflection on the paraboloidal Secondary (of total or conventional reflection) Mirror 231a,b (as extract of the relative complete paraboloidal Secondary Mirror 201a,b), the Narrow Beam of Rays 053a,b that reaches the Final Focus 204a,b and is characterized by the possibility of drastic reduction of the size of the Solar Idol (of the Solar Image when reflected) thus permitting concentration ratios in the order of 1000-2000 suns or even more and focuses on the PV Cells 302a lying at or behind the Final Focus 204a,b through the Final Focus Mirror 363b.
By that also in this position the Cooling Plates 302b of the PV Cells 302a can also be brought in direct contact with the Storage Water 310e, with result in this case that the Cooling Pipes 302d, the Circulating Pump 318a and the Spiral Heat Exchanger 318b are not needed any more and are deleted.
By that also the Focus Mirror 363a as a TRM, is constructed either by four Total Reflection Tiles forming a truncated pyramid around the PV Cells 302a with the acmes of their orthogonal prisms converging towards the top of the pyramid formed by them (or even from conventional mirrors air- or water-cooled) with a suitable opening angle towards the primary TRM 301a permitting it to compensate small aiming misalignments of the sun-tracking system or imperfections of the TRM 301a. By that also the Focus Mirror 363a can also be found at the Final Focus 204a,b (or at each Final Focus 204a,b of the successive TRM 301a combined each with its relative Secondary Mirror 231a,b as extract of the relative complete paraboloidal Secondary Mirror 201a,b), when a paraboloidal Secondary Mirror 231a,b is used to reflect back the Wide Beam 052a and form the Narrow Beam 053a,b towards the Final Focus 204a,b (named then Final Focus Mirror 363b).
By that also the Horizontal Rotation Axis 308a in the case that the PV Cells 302a are positioned at the Final Focus 204a,b can either carry fixed on it the Cooling Plates 302c [in this case the Axis 308a being hollow and being cooled by the Cooling Fluid 302e, which flows through it either circulated by the Circulating Pump 318d or directly by gravity when both ends of the Axis 308a are submerged in the Storage Water 310e (while the fixed on it Solar Cells 302a being protected from the water by the specially formulated watertight submerged Basin 308e around the submerged Axis 308a, which is drained from parasitic water by the Drainage Pipe 308h going out through the central Passing Through Cylinder 310c), while both ends of the 308a going through the end walls of the Basin 308e, into the Storage Water 310e, by the flexible Connections 308f permitting watertight rotation of the 308a by +/−90° in order to truck the Sun] or incorporating suitable openings containing the Final Focus Mirrors 363b with attached at their ends the PV Cells 302a, in this case being, through their Cooling Plates 302c, in direct contact with the Storage Water 310e and thus being directly cooled by it (the Solar Cells 302a being protected from the water by their watertight Basins 308g around each of the Final Focus Mirrors 363b).
By that also in this later case as well as in the case of the submerged Axis 308a above, with fixed on it the PV Cells 302a, the Cooling Pipes 302d, the Circulating Pump 318a and the Spiral Heat Exchanger 318b, not being needed any more are deleted.
By that also in the position of the submerged Horizontal Rotation Axis 308a the Bearings 308c are fixed on the specially arranged 310b with their head downwards coupled respectively with the relative Mechanism of Horizontal Rotation 308b.
It is further characterized by the special arrangement and positioning of the primary TRM 301a and the Secondary Mirror 231a,b as extracts of the complete Mirrors 361a and 201a,b, in successive positions, thus forming the complete S/S 300b.

3. A Solar System S/S 300a,b-S/E 900a which is materialised as the S/S 300a or S/S 300b in the claims 1 and 2 above, but it is characterized by the fact that alternatively the S/S 300a or S/S 300b instead of including a simple Focus Mirror 363a or 201a,b it includes a Focus Structural Element (S/E) 900a which is characterized by the fact that it is designed for the simultaneous production of electricity, hot water (from the cooling of the PV Cells) and overheated oil (for cooking as well as for the overheating of the domestic hot water as well as for the regulation of the ratio in the production of electrical and thermal energy of the S/S 300a or of whatsoever similar concentration PV System).
It is also characterized by the fact that the Sun Rays 051a after their falling on the relative Primary Parabolic Mirror i.e 301a with its Top at the point 362a, they create the reflected Wide Beam of Rays 052a which focalizes on the Focus 304a and afterward it falls on the PV Cells 302a, which can be found either at the Opening 912a of the Cavity 913a (which maybe i.e coincides with the Focus 304a), whereupon all the concentrated solar radiation (Wide Beam 052a) falls on the PV Cells 302a and is absorbed by them by that also the PV Cells can also be found in whatsoever depth in the Cavity 913a (moving backwards, in the Cavity 913a, the Cylinder of Support/Cooling 914a of the PV Cells 302a) whereupon only a part of the Wide Beam 052a falls and is absorbed on the PV Cells 302a while the rest falls on the Oil Pipes 915a, that cover the interior of the Cavity 913a, and is absorbed then by the special Overheating Oil 916a (which can reach temperatures up to 300°-400° C.).
Also by that the percentage of the concentrated solar radiation of the Wide Beam 052a, which is absorbed by the PV Cells 302a and by the Overheating Oil 916a, is depended on the position of withdrawal (or positioning) of the PV Cells 302a in the Cavity 913a and it is possible to be decreased to very small percentages for the extreme position of the PV cells (i.e. 5%), resulting to a relative increase of the absorbed percentage by the Overheated Oil 916a which absorbs then the 95%.
It is characterized by the Cylinder of Support/Cooling 914a of the PV Cells 302a which supports the PV Cells 302a while simultaneously, through the concentric Cooling Pipes 917a, transports and abducts the Cooling Fluid 302e of the PV Cells 302a. By that the Cooling Pipes 917a are linked, through the Flexible Pipes 918a, with the Pipes 302d of transportation to and from of the Cooling Fluid 302e which is conducted by them to the Spiral type Heat Exchanger 318b in the hot Water Container 310a. It is also characterized by the fact that the movement in and out of the cavity 913a, of the Cylinder of Support/ Cooling 914a is effected by the Mechanism 928a, which is constituted by the Moving Screw 928c that is connected with the Displacement Screw 928b which is fixed on the Supporting Cylinder 914a, from the Movement Screw 928c which is coupled with the Displacement Screw 928b, from the Coupling Axle 928d which connects the Movement Screws 928c of the successive S/E 900a (one for each TRM 301a), from the Motor 928e, which is connected with the Coupling Axle 928d, eventually through a reduction gear, and via the elements 928c and 928b transmits the movement forwards-backwards to the Cylinder 914a. Also by the fact that the Oil tubes 915a, which cover the interior of the Cavity 913a are conducted to the Exchanger 919a inside the hot water Container 310a and increase the temperature of the Storage Water 310e which originates from the cooling of the PV cells 302a, to the desired temperature.
Also it is characterized by the fact that before the Pipe of Overheated Oil 915d reaches the Exchanger 919a it can pass first trough the Exterior Mantle 920a of the high temperature Storage Container 921a where thermal energy is stored in high temperature in the Eutectic Salt 922a, which is contained in the Container 921a and subsequently is led in the Exchanger 919a.
Also by the fact that the Storage Container 921a bears a strong Insulation 926a with a removable Insulated Tap 923a of the upper Heating Plate 924a of the Container 921a, so that when the Insulated Tap 923a is removed the Heating Plate 924a can be used as a Cooking Herd in hours outside the peak of solar energy. Also by that the Overheated Oil 916c circulates in the Oil Pipes 915a via the Circulator 925a and the Cooling Fluid 302e circulates in the Pipes 302d via the Circulator 318a. Also by that the S/E 900a is supported on the correspondent Frame of Support 302b of the correspondent S/S i.e 300a (or whatsoever else concentrating PV System) via the 4 Supports 907a which can simultaneously play in pairs the role of the Water Pipes 302d and of the Oil Pipes 915a.

4. The Solar System of Single Point Focus S/S 100a [where with (a) is designated the S/S 100 when employing Total Reflection Mirrors], which is materialised as the S/S 300a or S/S 300b in the claims 1 and 2 above, but it is characterized by the fact that it is a Single Point Focus Solar System, which can achieve very high concentration ratios by employing total reflection mirrors.
Which is further characterized by that it includes a complete primary Parabolic Total Reflection Mirror PTRM 101a with its Top at the point 102a (which is further characterized by its Total Reflection Tiles (TRT) 131a, with their Front Surface 113a and their back Orthogonal Prisms 114a) and where the Solar Rays 051a after falling on the primary PTRM 101a create the first reflected Wide Beam of Rays 052a, which focus on the First Focus 104a and either they are exploited directly there by focusing on the PV Cells 302a with the help also of the Focal Mirror 119a (which is identical to the Focal Mirror 363a of claim 1 above) or alternatively after reflection on the Secondary Mirror 201a (that is supported via the Arms 207a on the Ring 105a), they create the Narrow Beam of Rays 053a, which reaches the Final Focus 204a and focuses on the PV Cells 302a also by the help of the Final Focus Mirror 119a, which is supported on the Ring 105c.
By that also the combination of the above Mirrors 101a and 201a is characterized by the possibility of drastic reduction of the size of the Solar Idol 053c (of the Solar Image when reflected), by reflectance of the Solar Rays 051a first on the PTRM 101a, forming the Wide Beam 052a and then by a second reflectance of the Wide Beam 052a on the concave paraboloidal Secondary Mirror 201a located behind the relative Focal Point 104a, thus forming the Narrow Beam 053a, which when focusing, under certain relations of sizing between the Mirrors 101a and 201a, can drastically reduce the size of the Solar Idol 053c (for example for a ratio of the diameter of the 101a to the one of the 201a equal to 4 the size of the Solar Idol at the Final Focus 204a can be reduced under the 20% of the size it would have without suppression) and so the concentration ratio of the relative S/S 100a can be increased to figures over 2000 Suns.
By that also the PTR Mirror 101a is supported on the metal Support Rings 105a (Exterior) and 105c (Interior), which on their turn are supported by the metal Support Arms 107a, which are supported on the Head of Horizontal Rotation 108a. The Head 108a is supported on the Column of Vertical Rotation 109a, which is based on the Base 110a, which is a fixed ground. By that also the Base 110a,b can carry on it one S/S 100a either with a complete primary Parabolic Total Reflection Mirror (PTRM) 101a or with a sector only of the PTRM 101a or whatsoever extract of the PTRM 101a and relative sectors or extracts of the secondary Paraboloidal Mirror 201a.
By that the Parabolic Total Reflection Mirror 101a is constituted for example from transparent water clear glass without iron oxides (in a single piece for small surfaces or constituted from Total Reflection Tiles (TRT) 131a that constitute parts of the Parabolic Surface 113′a for bigger surfaces supported on a suitable parabolic substrate) or from transparent plastic self-supported or supported on a suitable substrate. The Front Surface 113a of the 113′a has a smooth parabolic form, while the Rear Surface 113c is parabolic bas-relief and parallel with the 113a and is constituted from Orthogonal Prisms 114a, whose Top Acmes 115a converge and are intercepted at the Top 102a of the PTR Mirror 101a. By that the S/S 100a includes also the Axis of Symmetry 111a (which aims the Sun) and the Axes of Rotation 112a and 112c (Vertical and Horizontal respectively).
It is also characterized by the fact that the S/S 100a can include at its First Focus 104a, instead of the Focus Mirror 119a with the PV cells 302a, the paraboloidal Secondary Mirror 201a, (which is further characterized by its TRT 231a with their Front Surface 213a, their back Orthogonal Prisms 214a, their Acmes 215a converging to its Top 202a and their Back Surface 213c), is used to reflect back the Wide Beam 052a and form the Narrow Beam 053a towards the Final Focus 204a, where now the Focal Mirror 119a with the PV cells 302a will be located, (named then Final Focus Mirror 119a).
By that also alternatively the S/S 100a can include at its First Focus 104a or at its Final Focus 204a the Focus Structural Element S/E 900a like the S/S 300a and S/S 300b in claims 1 and 2 above.

5. The Solar System of Single Point Focus S/S 100b [where with (b) is designated the S/S 100 when employing Conventional Mirrors], which is constructed like the S/S 100a in claim 4 above but is characterized by that instead of employing total reflection mirrors it employs conventional reflection mirrors.

6. The Solar System of Single Point Focus S/S 100a,b [where with (a) is designated the S/S 100 when employing Total Reflection Mirrors and with (b) when employing Conventional Mirrors], which is constructed like the S/S 100a or S/S 100b in claim 4 and claim 5 above but is characterized by that it is based on the Base 110a,b, which is a Floating and Rotating Base 110a,b rotating to track the Sun, like the Base of Rotation 310b in claim 1 above, where therefore the Column of Vertical Rotation 109a,b will not be needed and will be deleted. By that also the Floating and Rotating Base 110a,b can carry on it one or more S/S 100a,b either with a complete primary Parabolic Total Reflection Mirror (PTRM) 101a,b or with a sector only of the PTRM 101a,b or whatsoever extract of the PTRM 101a,b and relative sectors or extracts of the secondary Paraboloidal Mirror 201a,b.

7. The combination of any of the concentrating type PV Systems in the claims 1, 2, 3, 4, 5 and 6 above with adsorption type heat-pump units, which utilize the low temperature of about (50°-90° C.) hot water produced from the cooling of the concentrating type solar cells in order to produce cold water of about (5°-14° C.) for air conditioning or cooling in refrigerators or refrigerator rooms etc. by using as adsorption medium for example silica gel, supported eventually by auxiliary hot water production boilers fired by conventional fuels, in order to cover periods of low solar radiation or non availability of the solar driven units.

8. Total Reflection Tablet TRT or TRM 1b constructed as given in the claims 1, 2, 3, 4 and 6 above, which is characterized by that it is of small thickness (i.e. 5-10 mm), from transparent material (i.e. water clear glass or transparent plastic i.e. Polycarbonate or Plexiglas etc with coefficient of diffraction <<n>> higher than 1.5 approx.), by that the Front Surface 1b-2 is flat while the Rear Surface 1b-1 is bas-relief consisting of many parallel orthogonal prisms. Therefore, the Total Reflection Tablet 1b represents a Total Reflection Mirror (TRM), which is characterized by its low cost of production from common water clear glass or from transparent plastic by impression in existing automatic machines with high production capacity, also by that the TRT don't need plating with Silver in order to make reflection and it doesn't appear aging etc
Furthermore it is characterized by the fact that the TRM 1b (and all the TRM in general) presents important advantages due to the Lateral Particularity of Total Reflection for example for maintaining the focus for a vibration oscillation of the TRM by +/−5° round an axis parallel with the along acme of the prism, also by the possibility of drastic reduction of the size of the solar Idol, by reflectance in a secondary TRM and thereinafter focusing etc.
It is also characterised by the fact that with the Total Reflection we have practically reflection of the 100% of radiation and in this way using TRM 1b etc allows the construction of Concentrating Solar Systems with multiple reflections before the final focus, with losses smaller than the losses from a single reflection in the concentrating systems with conventional mirrors.

9. A combination of the Reflectors 101a,b and 201a,b as given in the claims 1, 2, 3, 4, 5, 6 and 7 above or whatsoever extracts of them, which is characterized by the possibility of drastic reduction of the size of the Solar Idol 053c, by reflectance of the Solar Rays 051a first on the Reflector 101a,b forming the Wide Beam 052a and then by a second reflectance of the Wide Beam 052a on the 201a,b located behind the relative focal point, thus forming the Narrow Beam 053a, which when focusing, under certain relations of sizing between the Mirrors 101a,b and 201a,b, can drastically reduce the size of the Solar Idol 053c (for example for a ratio of the diameter of the 101a,b to the one of the 201a,b equal to 4, the size of the Solar Idol 053′c at the Final Focus 204a,b can be reduced under the 20% of the size, which the Solar Idol 053′c would have without suppression by the combination of the 101a,b and 201a,b as above) and so the concentration ratio of the relative S/S 100a,b can be increased to figures over 2000 Suns.

10. A further type of Total Reflection Mirror, the Focus Mirror 363a or 363b as given in the claims 1, 2, 3, 4, 5, 6 and 7 above, which is characterized by the fact that it is constructed either by four Total Reflection Tiles forming a truncated pyramid around the PV Cells 302a or even as a truncated conical TRM with a suitable opening angle (i.e. about 5°-20° greater from each side than the one facing the primary Reflector 301a or 101a,b or the secondary Reflector 201a,b respectively (or whatsoever extracts of the same), permitting it to compensate small aiming misalignments of the sun-tracking system or imperfections of the TRM 301a along its horizontal axis and up to +/−0.5° aiming misalignments of the sun-tracking system or imperfections of the primary Reflector 301a or 101a,b, or wind vibrations of the same by re-reflecting the deflected rays onto the Solar Cells 302a.
